(19) United States
(12) Patent Application Publication
(10) Pub. No.: US 2024/0379767 A1
(43) Pub. Date: Nov. 14, 2024

(54) SEMICONDUCTOR DEVICE, AND PRODUCTION METHOD FOR SEMICONDUCTOR DEVICE

(71) Applicant: SUMITOMO ELECTRIC INDUSTRIES, LTD., Osaka (JP)

(72) Inventor: Sadanori ARAE, Kanagawa (JP)

(21) Appl. No.: 18/645,813

(22) Filed: Apr. 25, 2024

(30) Foreign Application Priority Data
May 11, 2023 (JP) 2023-078808

(51) Int. Cl. H01L 29/20; H01L 21/311; H01L 23/373; H01L 29/417; H01L 29/66; H01L 29/778

(52) U.S. Cl. CPC H01L 29/2003; H01L 21/31116; H01L 23/3735; H01L 29/41725; H01L 29/66462; H01L 29/7786

(57) ABSTRACT

A semiconductor device includes a substrate; a semiconductor layer on the substrate; a first main electrode and a second main electrode that are on the semiconductor layer; a control electrode that is on the semiconductor layer and is between the first main electrode and the second main electrode; a first insulating layer that is in direct contact with the control electrode and covers the first main electrode; a second insulating layer on the first insulating layer; a first conductive layer that penetrates the first insulating layer and the second insulating layer, is electrically connected to the first main electrode, and is in direct contact with the first insulating layer; and a second conductive layer that is on the second insulating layer and is in direct contact with the first conductive layer. The first insulating layer includes aluminum nitride.

### CROSS-REFERENCE TO RELATED APPLICATIONS

This application is based on and claims priority to Japanese Patent Application No. 2023-078808, filed on May 11, 2023, the entire contents of which are incorporated herein by reference.

### TECHNICAL FIELD

The present disclosure relates to semiconductor devices, and production methods for semiconductor devices.

### BACKGROUND

In semiconductor devices including a high electron mobility transistor (HEMT), a gate electrode, a source electrode, and a drain electrode are covered with an insulating layer. See, for example, Japanese Patent Application Publication No. 2020-017647.

### SUMMARY

A semiconductor device of the present disclosure includes: a substrate; a semiconductor layer on the substrate; a first main electrode and a second main electrode that are on the semiconductor layer; a control electrode that is on the semiconductor layer and is between the first main electrode and the second main electrode; a first insulating layer that is in direct contact with the control electrode and covers the first main electrode; a second insulating layer on the first insulating layer; a first conductive layer that penetrates the first insulating layer and the second insulating layer, is electrically connected to the first main electrode, and is in direct contact with the first insulating layer; and a second conductive layer that is on the second insulating layer and is in direct contact with the first conductive layer. The first insulating layer includes aluminum nitride.

### BRIEF DESCRIPTION OF THE DRAWINGS

FIG. 1 is a cross-sectional diagram illustrating a semiconductor device according to a first embodiment;

FIG. 2 is a cross-sectional diagram illustrating a production method for the semiconductor device according to the first embodiment (part 1);

FIG. 3 is a cross-sectional diagram illustrating a production method for the semiconductor device according to the first embodiment (part 2);

FIG. 4 is a cross-sectional diagram illustrating a production method for the semiconductor device according to the first embodiment (part 3);

FIG. 5 is a cross-sectional diagram illustrating a production method for the semiconductor device according to the first embodiment (part 4);

FIG. 6 is a cross-sectional diagram illustrating a production method for the semiconductor device according to the first embodiment (part 5);

FIG. 7 is a cross-sectional diagram illustrating a production method for the semiconductor device according to the first embodiment (part 6);

FIG. 8 is a cross-sectional diagram illustrating a production method for the semiconductor device according to the first embodiment (part 7);

FIG. 9 is a cross-sectional diagram illustrating a production method for the semiconductor device according to the first embodiment (part 8);

FIG. 10 is a cross-sectional diagram illustrating a production method for the semiconductor device according to the first embodiment (part 9);

FIG. 11 is a cross-sectional diagram illustrating a semiconductor device according to a second embodiment;

FIG. 12 is a cross-sectional diagram illustrating a production method for the semiconductor device according to the second embodiment (part 1);

FIG. 13 is a cross-sectional diagram illustrating a production method for the semiconductor device according to the second embodiment (part 2);

FIG. 14 is a cross-sectional diagram illustrating a production method for the semiconductor device according to the second embodiment (part 3);

FIG. 15 is a cross-sectional diagram illustrating a production method for the semiconductor device according to the second embodiment (part 4);

FIG. 16 is a cross-sectional diagram illustrating a production method for the semiconductor device according to the second embodiment (part 5);

FIG. 17 is a cross-sectional diagram illustrating a production method for the semiconductor device according to the second embodiment (part 6);

FIG. 18 is a cross-sectional diagram illustrating a production method for the semiconductor device according to the second embodiment (part 7);

FIG. 19 is a cross-sectional diagram illustrating a production method for the semiconductor device according to the second embodiment (part 8);

FIG. 20 is a cross-sectional diagram illustrating a production method for the semiconductor device according to the second embodiment (part 9);

FIG. 21 is a cross-sectional diagram illustrating a production method for the semiconductor device according to the second embodiment (part 10);

FIG. 22 is a cross-sectional diagram illustrating a semiconductor device according to a third embodiment;

FIG. 23 is a cross-sectional diagram illustrating a semiconductor device according to a fourth embodiment; and

FIG. 24 is a cross-sectional diagram illustrating a semiconductor device according to a fifth embodiment.

### DETAILED DESCRIPTION

In recent years, the amount of heat generated has been increasing in accordance with higher output and higher frequency. Therefore, further improvement in heat dissipation is desired.

The present disclosure provides a semiconductor device capable of improving heat dissipation and a production method for the semiconductor device.

According to the present disclosure, it is possible to improve heat dissipation.

### Description of Embodiments of the Present Disclosure

First, embodiments of the present disclosure will be described below.

[1] A semiconductor device according to one aspect of the present disclosure includes: a substrate; a semiconductor layer on the substrate; a first main electrode and a second main electrode that are on the semiconductor layer; a control electrode that is on the semiconductor layer and is between the first main electrode and the second main electrode; a first insulating layer that is in direct contact with the control electrode and covers the first main electrode; a second insulating layer on the first insulating layer; a first conductive layer that penetrates the first insulating layer and the second insulating layer, is electrically connected to the first main electrode, and is in direct contact with the first insulating layer; and a second conductive layer that is on the second insulating layer and is in direct contact with the first conductive layer, in which the first insulating layer includes aluminum nitride.

During driving of a semiconductor device, heat tends to be generated near a control electrode of a semiconductor layer. The generated heat not only diffuses toward the substrate but also toward the control electrode. In the above semiconductor device, the first insulating layer is in direct contact with the control electrode, the first insulating layer is in direct contact with the first conductive layer, and the first conductive layer is in direct contact with the second conductive layer. With this configuration, heat that has reached the control electrode is transferred to the second conductive layer via the first insulating layer and the first conductive layer. Also, the first insulating layer includes aluminum nitride. Because aluminum nitride has high thermal conductivity, it is possible to dissipate heat from the second conductive layer with high efficiency. That is, it is possible to improve heat dissipation.

[2] In [1], the first insulating layer may be in direct contact with the semiconductor layer. In this case, heat generated in the semiconductor layer can be transferred to the second conductive layer with higher efficiency.

[3] In [1] or [2], resistance of the first insulating layer to etching using a fluorine-containing reactive gas may be higher than resistance of the second insulating layer to etching using the fluorine-containing reactive gas. In this case, a contact hole for forming the first conductive layer is readily formed.

[4] In any one of [1] to [3], the semiconductor device may further include a third insulating layer that is between the first main electrode and the first insulating layer and that the first conductive layer penetrates, and resistance of the third insulating layer to etching using a chlorine-containing reactive gas may be higher than resistance of the first insulating layer to etching using the chlorine-containing reactive gas. In this case, a contact hole for forming the first conductive layer is readily formed.

[5] In [4], between the first main electrode and the second conductive layer, a distance between the first main electrode and the first insulating layer may be larger than a distance between the second conductive layer and the first insulating layer. In this case, compared to when the distance between the first main electrode and the first insulating layer is smaller than the distance between the second conductive layer and the first insulating layer, a transfer path of heat in the first conductive layer can be shortened. Thus, heat can be transferred to the second conductive layer with higher efficiency.

[6] In [4] or [5], the first main electrode may include a third conductive layer that is in direct contact with the first conductive layer and the third insulating layer, and resistance of the third conductive layer to etching using a fluorine-containing reactive gas may be higher than resistance of the third insulating layer to etching using the fluorine-containing reactive gas. In this case, a contact hole for forming the first conductive layer is readily formed.

[7] In [6], the third conductive layer may be a titanium layer. In this case, the third conductive layer readily has high resistance to etching using the fluorine-containing reactive gas.

[8] In any one of [1] to [7], the semiconductor device may further include: a fourth conductive layer that penetrates the first insulating layer and the second insulating layer, is electrically connected to the second main electrode, and is in direct contact with the first insulating layer; and a fifth conductive layer that is on the second insulating layer and is in direct contact with the fourth conductive layer. In this case, the number of transfer paths of heat increases, thereby achieving a higher extent of heat dissipation.

[9] In [8], the semiconductor device may further include a fourth insulating layer that is between the second main electrode and the first insulating layer and that the fourth conductive layer penetrates, and resistance of the fourth insulating layer to etching using a chlorine-containing reactive gas may be higher than resistance of the first insulating layer to etching using the chlorine-containing reactive gas. In this case, a contact hole for forming the fourth conductive layer is readily formed.

[10] In [9], between the second main electrode and the fifth conductive layer, a distance between the second main electrode and the first insulating layer may be larger than a distance between the fifth conductive layer and the first insulating layer. In this case, compared to when the distance between the second main electrode and the first insulating layer is smaller than the distance between the fifth conductive layer and the first insulating layer, a transfer path of heat in the fourth conductive layer can be shortened. Thus, heat can be transferred to the fifth conductive layer with higher efficiency.

[11] In [9] or [10], the second main electrode may include a sixth conductive layer that is in direct contact with the fourth conductive layer and the fourth insulating layer, and resistance of the sixth conductive layer to etching using a fluorine-containing reactive gas may be higher than resistance of the fourth insulating layer to etching using the fluorine-containing reactive gas. In this case, a contact hole for forming the fourth conductive layer is readily formed.

[12] In [11], the sixth conductive layer may be a titanium layer. In this case, the sixth conductive layer readily has high resistance to etching using the fluorine-containing reactive gas.

[13] A production method for a semiconductor device according to another aspect of the present disclosure includes: forming a semiconductor layer on a substrate; forming a first main electrode and a second main electrode on the semiconductor layer; forming a control electrode on the semiconductor layer and between the first main electrode and the second main electrode; forming a first insulating layer so as to be in direct contact with the control electrode and cover the first main electrode; forming a second insulating layer on the first insulating layer; forming a contact hole in the first insulating layer and the second insulating layer so as to penetrate the first insulating layer and the second insulating layer and reach the first main electrode; forming a first conductive layer in the contact hole so as to be electrically connected to the first main electrode and be in direct contact with the first insulating layer; and forming a second conductive layer on the second insulating layer so as to be in direct contact with the first conductive layer, in which the first insulating layer includes aluminum nitride.

During driving of a semiconductor device, heat tends to be generated near a control electrode of a semiconductor layer. The generated heat not only diffuses toward the substrate but also toward the control electrode. In the produced semiconductor device, the first insulating layer is in direct contact with the control electrode, the first insulating layer is in direct contact with the first conductive layer, and the first conductive layer is in direct contact with the second conductive layer. With this configuration, heat that has reached the control electrode is transferred to the second conductive layer via the first insulating layer and the first conductive layer. Also, the first insulating layer includes aluminum nitride. Because aluminum nitride has high thermal conductivity, it is possible to dissipate heat from the second conductive layer with high efficiency. That is, it is possible to improve heat dissipation.

[14] In [13], resistance of the first insulating layer to etching using a fluorine-containing reactive gas may be higher than resistance of the second insulating layer to etching using the fluorine-containing reactive gas, and the formation of the contact hole may include: forming a first opening so as to penetrate the second insulating layer and reach the first insulating layer by etching using the fluorine-containing reactive gas; and forming a second opening so as to penetrate the first insulating layer by etching of a portion of the first insulating layer exposed from the first opening. In this case, for the formation of the first opening, the first insulating layer functions as an etching stopper. Therefore, a contact hole is readily formed.

[15] In [14], the production method for the semiconductor device may further include forming a third insulating layer on the first main electrode between the formation of the first main electrode and the second main electrode and the formation of the first insulating layer, resistance of the third insulating layer to etching using a chlorine-containing reactive gas may be higher than resistance of the first insulating layer to etching using the chlorine-containing reactive gas, the first insulating layer may cover the third insulating layer, and the formation of the second opening may include etching the portion of the first insulating layer exposed from the first opening using the chlorine-containing reactive gas. In this case, for the formation of the second opening, the third insulating layer functions as an etching stopper. Therefore, a contact hole is readily formed.

[16] In [15], the formation of the first main electrode may include forming a third conductive layer so as to be in direct contact with the third insulating layer, resistance of the third conductive layer to etching using a fluorine-containing reactive gas may be higher than resistance of the third insulating layer to etching using the fluorine-containing reactive gas, and the formation of the contact hole may include forming a third opening so as to penetrate the third insulating layer by etching of a portion of the third insulating layer exposed from the second opening using the fluorine-containing reactive gas. In this case, for the formation of the third opening, the third conductive layer functions as an etching stopper. Therefore, a contact hole is readily formed.

### Details of Embodiments of Present Disclosure

Embodiments of the present disclosure will be described below in detail, but the present disclosure is not limited thereto. In the present specification and drawings, components having substantially the same functional configuration are denoted by the same reference numerals, and duplicate description thereof may be omitted.

### First Embodiment

The first embodiment will be described below. The first embodiment relates to a semiconductor device including a gallium nitride (GaN)-based high electron mobility transistor (HEMT).

### [Configuration of Semiconductor Device]

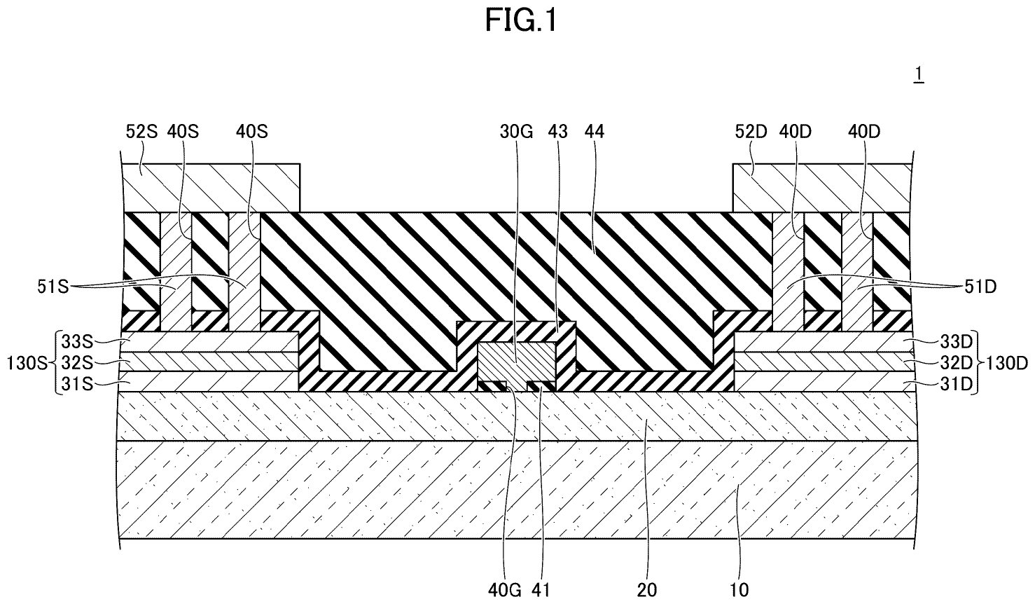

First, the configuration of the semiconductor device according to the first embodiment will be described. FIG. 1 is a cross-sectional diagram illustrating the semiconductor device according to the first embodiment.

As illustrated in FIG. 1, a semiconductor device 1 according to the first embodiment includes a substrate 10, a semiconductor layer 20, a gate electrode 30G, a source electrode 130S, and a drain electrode 130D. The semiconductor device 1 further includes insulating layers 41, 43, and 44, a plurality of conductive plugs 51S, a plurality of conductive plugs 51D, a source interconnect 52S, and a drain interconnect 52D.

The substrate 10 is, for example, a silicon carbide (SiC) substrate. The semiconductor layer 20 is provided on the substrate 10. The semiconductor layer 20 is, for example, a nitride semiconductor layer including gallium (Ga). The nitride semiconductor layer forms a part of a high electron mobility transistor, such as an electron travel layer (channel layer), an electron supply layer (barrier layer), or the like. Two-dimensional gas (2DEG) exists in the semiconductor layer 20, and a part in which the 2DEG exists functions as a channel.

The source electrode 130S is provided on the semiconductor layer 20. The source electrode 130S includes, for example, a tantalum (Ta) layer 31S, an aluminum (Al) layer 32S, and a Ta layer 33S. The Ta layer 31S is provided on the semiconductor layer 20. The Al layer 32S is provided on the Ta layer 31S. The Ta layer 33S is provided on the Al layer 32S. The source electrode 130S makes an ohmic contact with the semiconductor layer 20. The source electrode 130S is an example of the first main electrode or the second main electrode.

The drain electrode 130D is provided on the semiconductor layer 20 and apart from the source electrode 130S. The drain electrode 130D includes, for example, a Ta layer 31D, an Al layer 32D, and a Ta layer 33D. The Ta layer 31D is provided on the semiconductor layer 20. The Al layer 32D is provided on the Ta layer 31D. The Ta layer 33D is provided on the Al layer 32D. The drain electrode 130D makes an ohmic contact with the semiconductor layer 20. The drain electrode 130D is an example of the first main electrode or the second main electrode.

The insulating layer 41 is provided on the semiconductor layer 20 between the source electrode 130S and the drain electrode 130D. The insulating layer 41 is, for example, a silicon nitride (SiN) layer. The thickness of the insulating layer 41 is, for example, 5 nm or larger and 500 nm or smaller. An opening 40G is formed in the insulating layer 41. The semiconductor layer 20 is exposed from the opening 40G. The gate electrode 30G is provided on the insulating layer 41. A part of the gate electrode 30G is in the opening 40G, and the gate electrode 30G is in direct contact with the semiconductor layer 20 through the opening 40G. The gate electrode 30G makes a Schottky contact with the semiconductor layer 20. The gate electrode 30G has a T shape in a cross-sectional view. The gate electrode 30G includes, for example, a nickel (Ni) layer and a gold (Au) layer provided on the Ni layer. The gate electrode 30G is an example of the control electrode.

The insulating layer 43 covers the gate electrode 30G, the insulating layer 41, the semiconductor layer 20, the source electrode 130S, and the drain electrode 130D. The insulating layer 43 is in direct contact with the gate electrode 30G, the insulating layer 41, the semiconductor layer 20, the source electrode 130S, and the drain electrode 130D. The insulating layer 43 includes aluminum nitride (AlN). For example, the insulating layer 43 may be an AlN layer. The thermal conductivity of AlN is 20 W/(m·K) or higher, which may be varied with the composition thereof, and is higher than the thermal conductivity of commonly used SiN. The thickness of the insulating layer 43 is, for example, 5 nm or larger and 1,000 nm or smaller. The insulating layer 43 is an example of the first insulating layer.

The insulating layer 44 is provided on the insulating layer 43. The resistance of the insulating layer 43 to etching using the fluorine-containing reactive gas is higher than the resistance of the insulating layer 44 to etching using the fluorine-containing reactive gas. The insulating layer 44 is, for example, a silicon oxide (SiO) layer. The thickness of the insulating layer 44 is, for example, 50 nm or larger and 5,000 nm or smaller. The insulating layer 44 is an example of the second insulating layer.

A plurality of contact holes 40S and a plurality of contact holes 40D are formed in the insulating layers 43 and 44. The contact holes 40S penetrate the insulating layers 43 and 44, and the contact holes 40D penetrate the insulating layers 43 and 44. The source electrode 130S is exposed from the contact holes 40S, and the drain electrode 130D is exposed from the contact holes 40D. The conductive plugs 51S are provided in the contact holes 40S, and the conductive plugs 51D are provided in the contact holes 40D. Both the conductive plugs 51S and the conductive plugs 51D include, for example, an adhesion film and a tungsten (W) film provided on the adhesion film. The adhesion film includes, for example, a titanium nitride (TiN) film and a titanium (Ti) film provided on the TiN film. The conductive plugs 51S penetrate the insulating layers 43 and 44, and are electrically connected to the source electrode 130S. The conductive plugs 51S are in direct contact with the insulating layer 43. The conductive plugs 51D penetrate the insulating layers 43 and 44, and are electrically connected to the drain electrode 130D. The conductive plugs 51D are in direct contact with the insulating layer 43. The conductive plug 51S is an example of the first conductive layer or the fourth conductive layer, and the conductive plug 51D is an example of the first conductive layer or the fourth conductive layer.

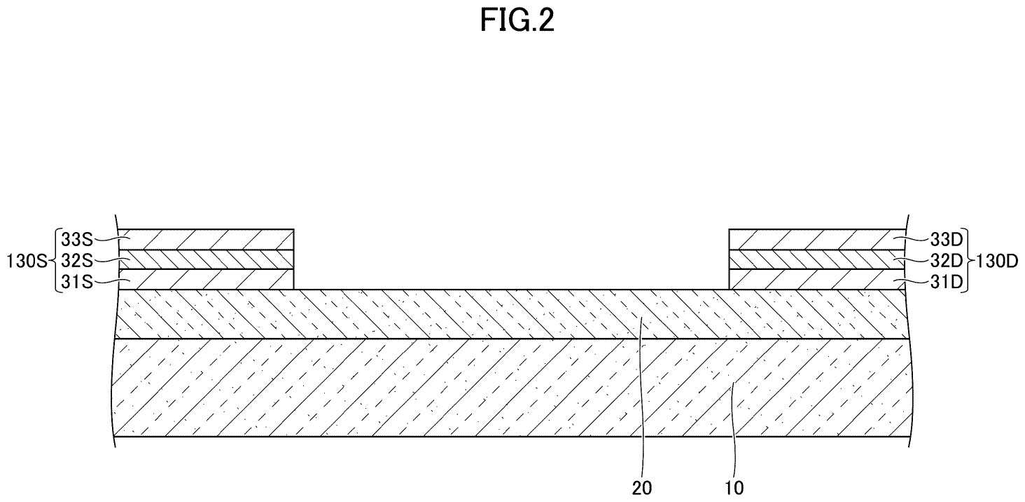

The source interconnect 52S is provided on the insulating layer 44. The source interconnect 52S is in direct contact with the conductive plugs 51S. The drain interconnect 52D is provided on the insulating layer 44. The drain interconnect 52D is in direct contact with the conductive plugs 51D. Both the source interconnect 52S and the drain interconnect 52D include, for example, an Au layer or an Al layer. The source interconnect 52S is an example of the second conductive layer or the fifth conductive layer, and the drain interconnect 52D is an example of the second conductive layer or the fifth conductive layer.

[Production Method for Semiconductor Device]Next, a production method for the semiconductor device 1 according to the first embodiment will be described. FIG. 2 to FIG. 10 are cross-sectional diagrams illustrating the production method for the semiconductor device 1 according to the first embodiment.

First, as illustrated in FIG. 2, the semiconductor layer 20 is formed on the substrate 10, for example, through metal organic chemical vapor deposition (MOCVD). Next, the source electrode 130S and the drain electrode 130D are formed on the semiconductor layer 20. For the formation of the source electrode 130S and the drain electrode 130D, for example, a Ta layer, an Al layer, and a Ta layer are grown through vapor deposition using a growth mask, followed by removal of the growth mask. That is, the source electrode 130S and the drain electrode 130D can be formed, for example, through vapor deposition and lift-off.

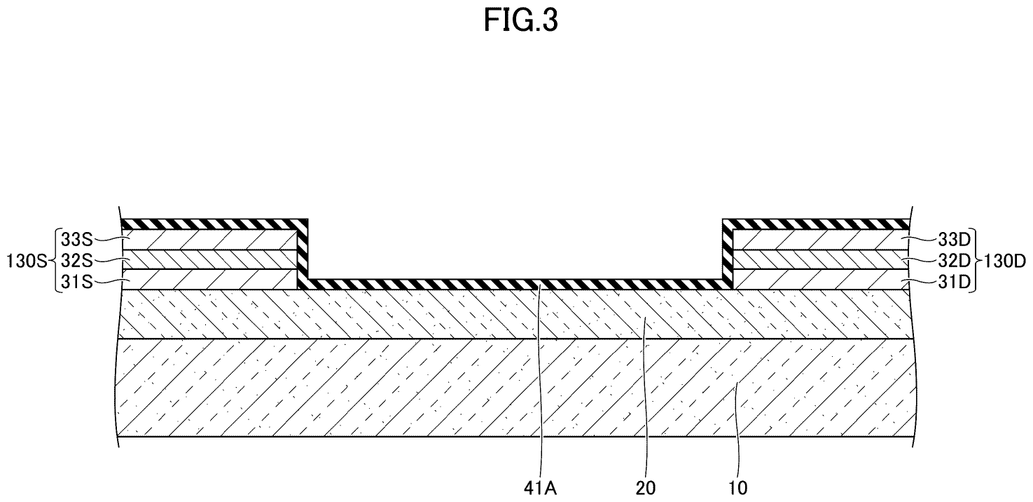

Next, as illustrated in FIG. 3, an insulating layer 41A covering the semiconductor layer 20, the source electrode 130S, and the drain electrode 130D is formed. The insulating layer 41A can be formed, for example, through plasma CVD. The insulating layer 41A is, for example, an SiN layer. The thickness of the insulating layer 41A is, for example, 5 nm or larger and 500 nm or smaller.

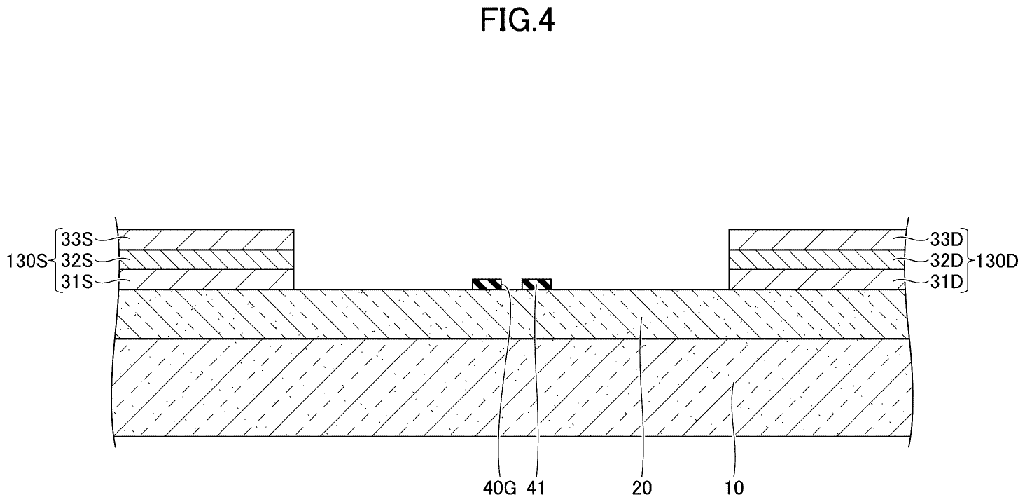

Next, by etching the insulating layer 41A, an insulating layer 41 having the opening 40G is formed from the insulating layer 41A, as illustrated in FIG. 4. For the formation of the insulating layer 41, for example, reactive ion etching (RIE) of the insulating layer 41A using a resist pattern as a mask is performed. In the RIE of the insulating layer 41A, for example, a fluorine-containing reactive gas is used.

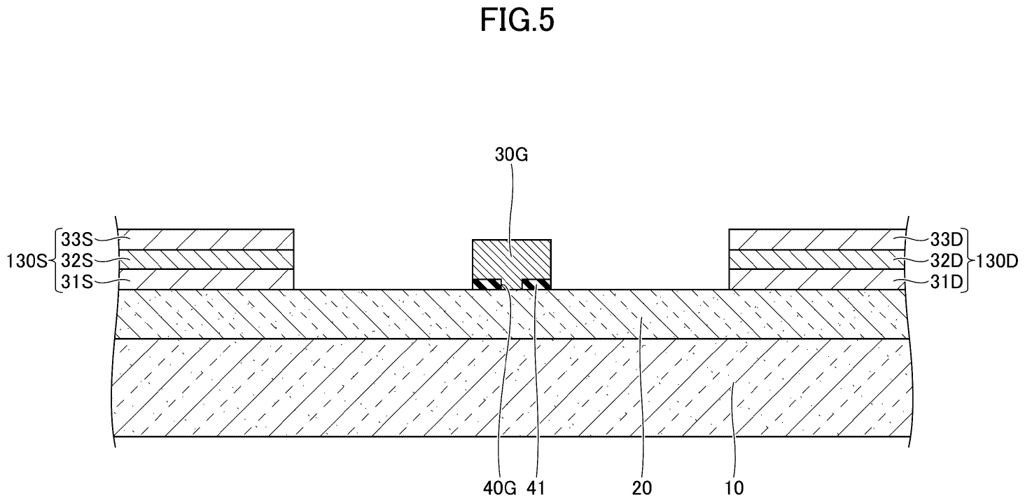

Next, as illustrated in FIG. 5, the gate electrode 30G is formed on the insulating layer 41. For the formation of the gate electrode 30G, for example, an Ni layer and an Au layer are grown through vapor deposition using a growth mask, followed by removal of the growth mask. That is, the gate electrode 30G can be formed, for example, through vapor deposition and lift-off.

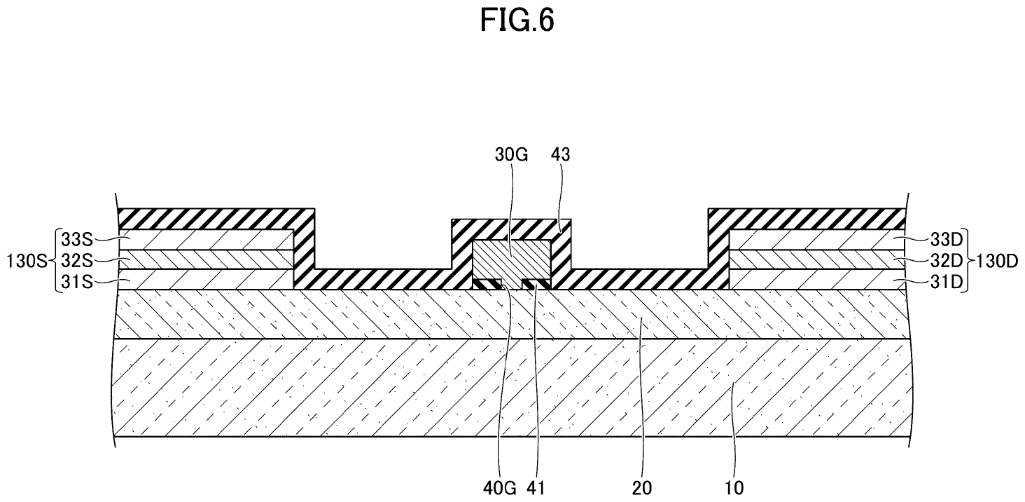

Next, as illustrated in FIG. 6, the insulating layer 43 is formed to cover the gate electrode 30G, the insulating layer 41, the semiconductor layer 20, the source electrode 130S, and the drain electrode 130D. The insulating layer 43 is, for example, an AlN layer. The insulating layer 43 can be formed, for example, through plasma CVD or atomic layer deposition (ALD).

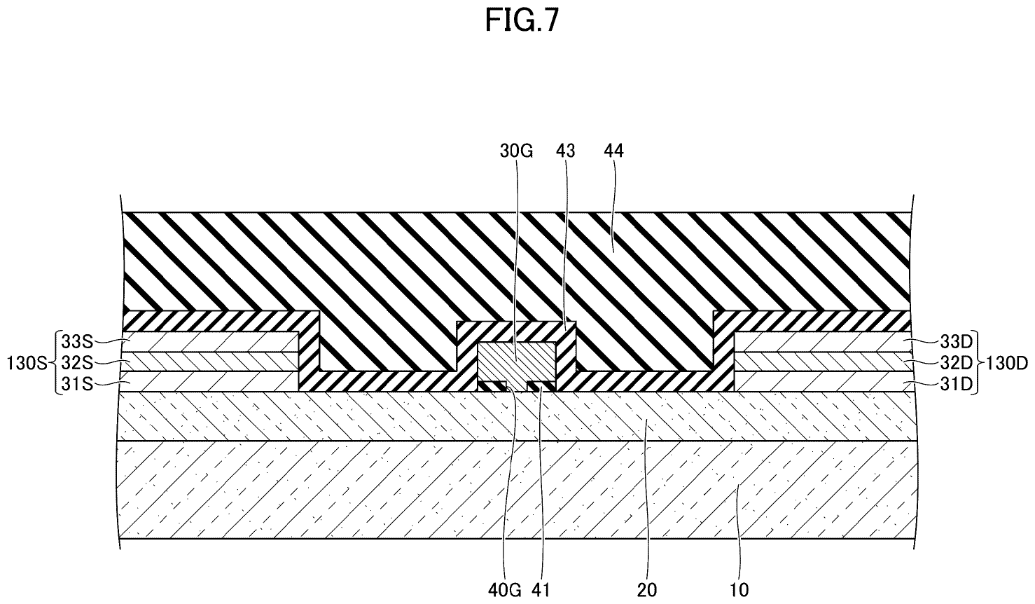

Next, as illustrated in FIG. 7, the insulating layer 44 is formed on the insulating layer 43. The insulating layer 44 is, for example, an SiO₂ layer. The insulating layer 44 can be formed, for example, through plasma CVD. The surface of the insulating layer 44 may be smoothed through chemical mechanical polishing (CMP) or the like.

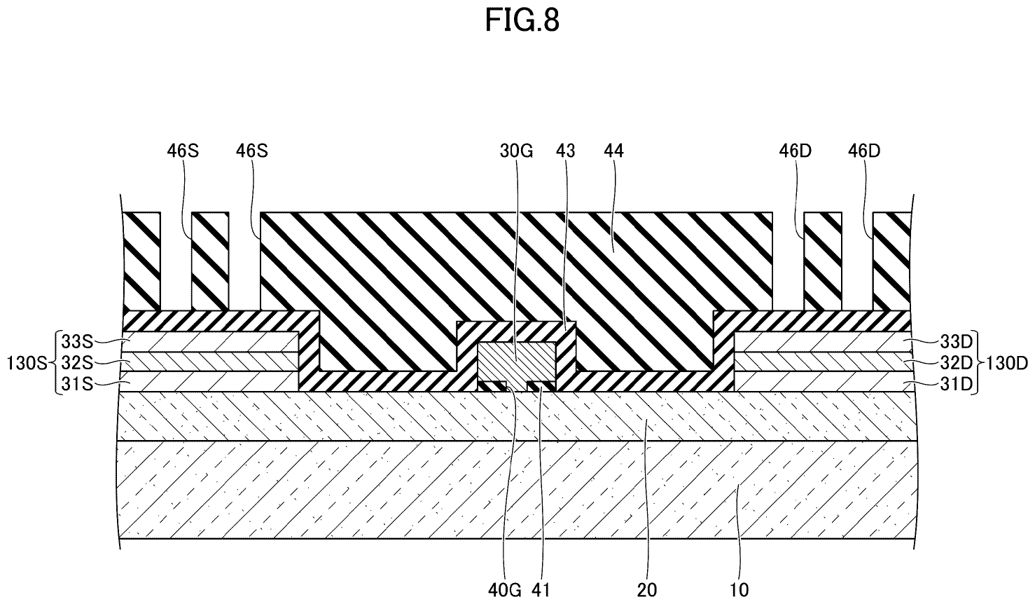

Next, as illustrated in FIG. 8, a plurality of openings 46S and a plurality of openings 46D are formed in the insulating layer 44. The openings 46S are formed in portions of the insulating layer 44 where the contact holes 40S are to be formed, and the openings 46D are formed in portions of the insulating layer 44 where the contact holes 40D are to be formed. For the formation of the openings 46S and the openings 46D, for example, RIE of the insulating layer 44 using a resist pattern as a mask is performed. In the RIE of the insulating layer 44, for example, a fluorine-containing reactive gas, such as trifluoromethane (CHF₃) or the like, is used. Here, the resistance of the insulating layer 43 to etching using the fluorine-containing reactive gas is higher than the resistance of the insulating layer 44 to etching using the fluorine-containing reactive gas. Thus, the insulating layer 43 is not appreciably etched, and the insulating layer 43 functions as an etching stopper.

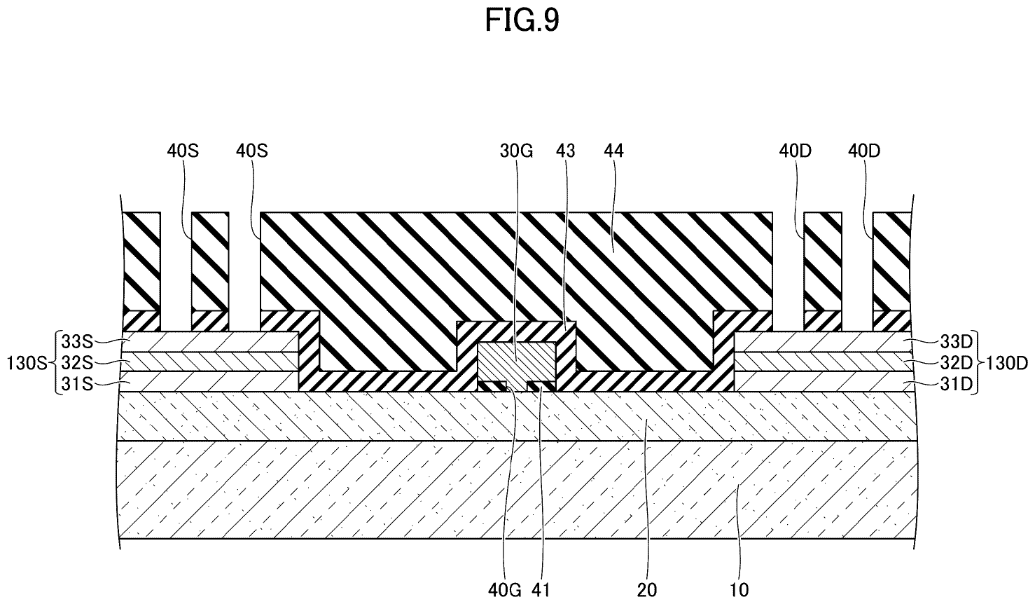

Next, as illustrated in FIG. 9, by etching portions of the insulating layer 43 that are exposed from the openings 46S and portions of the insulating layer 43 that are exposed from the openings 46D, thereby extending the openings 46S and the openings 46D, the contact holes 40S and the contact holes 40D are formed in the insulating layers 43 and 44. The contact holes 40S and the contact holes 40D penetrate the insulating layers 43 and 44. For the etching of the insulating layer 43, for example, RIE of the insulating layer 43 using a resist pattern as a mask is performed. In the RIE of the insulating layer 43, for example, a chlorine-containing reactive gas and an argon (Ar) plasma are used. In the contact holes 40S and the contact holes 40D, the portions formed in the insulating layer 44 are an example of the first opening, and the portions formed in the insulating layer 43 are an example of the second opening.

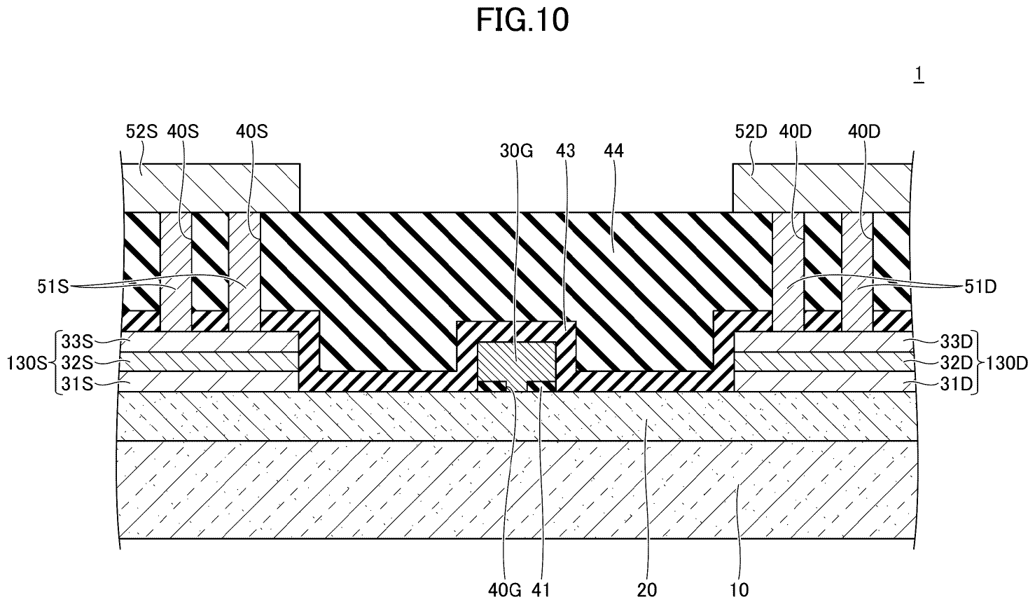

Next, as illustrated in FIG. 10, the conductive plugs 51S are formed in the contact holes 40S, and the conductive plugs 51D are formed in the contact holes 40D. The conductive plugs 51S and the conductive plugs 51D can be formed, for example, through CVD. Next, the source interconnect 52S and the drain interconnect 52D are formed on the insulating layer 44. The source interconnect 52S is formed to be in direct contact with the conductive plugs 51S, and the drain interconnect 52D is formed to be in direct contact with the conductive plug 51D. For the formation of the source interconnect 52S and the drain interconnect 52D, for example, the Au layer is grown through vapor deposition using a growth mask, followed by removal of the growth mask. That is, the source interconnect 52S and the drain interconnect 52D can be formed, for example, through vapor deposition and lift-off. In the formation of the source interconnect 52S and the drain interconnect 52D, an Al layer may be formed over the entirety of upper surfaces of the insulating layer 44, the conductive plugs 51S, and the conductive plugs 51D, and then the Al layer may be dry-etched.

In this manner, the semiconductor device 1 according to the first embodiment can be produced.

During driving of the semiconductor device 1 according to the first embodiment, heat tends to be generated near the channel of the semiconductor layer 20, especially near the gate electrode 30G. The heat generated near the gate electrode 30G not only diffuses toward the substrate 10 but also toward the gate electrode 30G. In the present embodiment, the insulating layer 43 is in direct contact with the gate electrode 30G, the insulating layer 43 is in direct contact with the conductive plugs 51S and the conductive plugs 51D, the conductive plugs 51S are in direct contact with the source interconnect 52S, and the conductive plugs 51D are in direct contact with the drain interconnect 52D. Therefore, the heat that has reached the gate electrode 30G is transferred to the source interconnect 52S via the insulating layer 43 and the conductive plugs 51S, or is transferred to the drain interconnect 52D via the insulating layer 43 and the conductive plugs 51D. The insulating layer 43 includes aluminum nitride. According to the present embodiment, because aluminum nitride has high thermal conductivity, it is possible to discharge the heat from the source interconnect 52S and the drain interconnect 52D with high efficiency. That is, according to the present embodiment, it is possible to improve heat dissipation.

Because the insulating layer 43 is in direct contact with the semiconductor layer 20, it is possible to transfer the heat generated in the semiconductor layer 20 to the source interconnect 52S and the drain interconnect 52D with higher efficiency.

The transfer path of heat from the gate electrode 30G may be either the transfer path to the source interconnect 52S or the transfer path to the drain interconnect 52D. However, by the presence of two transfer paths, a higher extent of heat dissipation can be achieved.

### Second Embodiment

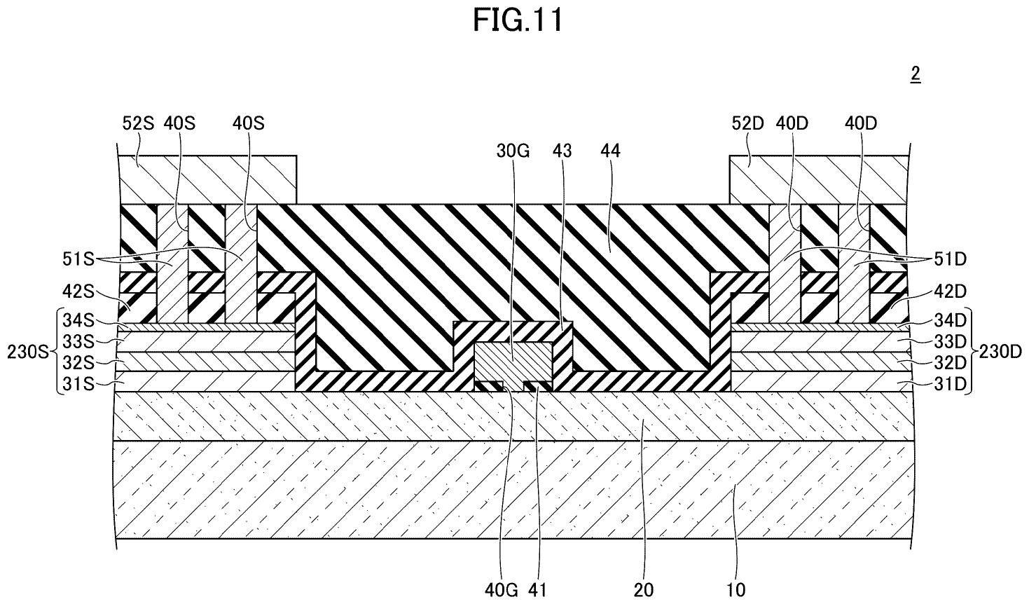

The second embodiment will be described below. The second embodiment differs from the first embodiment mainly in terms of the configuration of the source electrode, the drain electrode, and the insulating layer.

[Configuration of Semiconductor Device]First, the configuration of the semiconductor device according to the second embodiment will be described. FIG. 11 is a cross-sectional diagram illustrating the semiconductor device according to the second embodiment.

As illustrated in FIG. 11, a semiconductor device 2 according to the second embodiment includes a source electrode 230S instead of the source electrode 130S and a drain electrode 230D instead of the drain electrode 130D. The semiconductor device 2 also includes insulating layers 42S and 42D.

The source electrode 230S is provided on the semiconductor layer 20. The source electrode 230S includes, for example, the Ta layer 31S, the Al layer 32S, the Ta layer 33S, and a Ti layer 34S. The Ta layer 31S is provided on the semiconductor layer 20. The Al layer 32S is provided on the Ta layer 31S. The Ta layer 33S is provided on the Al layer 32S. The Ti layer 34S is provided on the Ta layer 33S. The thickness of the Ti layer 34S is, for example, 5 nm or larger and 200 nm or smaller. The source electrode 230S makes an ohmic contact with the semiconductor layer 20. The source electrode 230S is an example of the first main electrode or the second main electrode. The Ti layer 34S is an example of the third conductive layer or the sixth conductive layer.

The drain electrode 230D is provided on the semiconductor layer 20 and apart from the source electrode 230S. The drain electrode 230D includes, for example, the Ta layer 31D, the Al layer 32D, the Ta layer 33D, and a Ti layer 34D. The Ta layer 31D is provided on the semiconductor layer 20. The Al layer 32D is provided on the Ta layer 31D. The Ta layer 33D is provided on the Al layer 32D. The Ti layer 34D is provided on the Ta layer 33D. The thickness of the Ti layer 34D is, for example, 5 nm or larger and 200 nm or smaller. The drain electrode 230D makes an ohmic contact with the semiconductor layer 20. The drain electrode 230D is an example of the first main electrode or the second main electrode. The Ti layer 34D is an example of the third conductive layer or the sixth conductive layer.

The insulating layer 42S is provided on the Ti layer 34S. The insulating layer 42D is provided on the Ti layer 34D. The resistance of the Ti layers 34S and 34D to etching using the fluorine-containing reactive gas is higher than the resistance of the insulating layers 42S and 42D to etching using the fluorine-containing reactive gas. The resistance of the insulating layers 42S and 42D to etching using the chlorine-containing reactive gas is higher than the resistance of the insulating layer 43 to etching using the chlorine-containing reactive gas. The insulating layers 42S and 42D are, for example, an SiO₂ layer. The thickness of the insulating layers 42S and 42D is, for example, 50 nm or larger and 5,000 nm or smaller. The insulating layer 42S is an example of the third insulating layer or the fourth insulating layer, and the insulating layer 42D is an example of the third insulating layer or the fourth insulating layer.

The insulating layer 43 covers the gate electrode 30G, the insulating layer 41, the semiconductor layer 20, the insulating layer 42S, the insulating layer 42D, the source electrode 230S, and the drain electrode 230D. The insulating layer 43 is in direct contact with the gate electrode 30G, the insulating layer 41, the semiconductor layer 20, the insulating layer 42S, the insulating layer 42D, the source electrode 230S, and the drain electrode 230D.

The contact holes 40S are formed in the insulating layers 42S, 43, and 44, and the contact holes 40D are formed in the insulating layers 42D, 43, and 44. The contact holes 40S penetrate the insulating layers 42S, 43, and 44, and the contact holes 40D penetrate the insulating layers 42D, 43, and 44. The source electrode 230S is exposed from the contact holes 40S, and the drain electrode 230D is exposed from the contact holes 40D. The conductive plugs 51S penetrate the insulating layers 42S, 43, and 44, and are electrically connected to the source electrode 230S. The conductive plugs 51D penetrate the insulating layers 42D, 43, and 44, and are electrically connected to the drain electrode 130D.

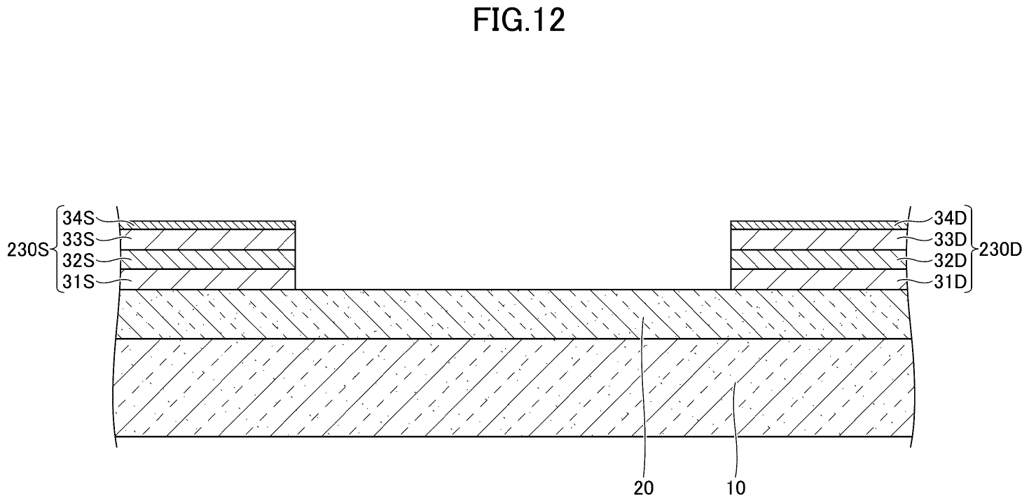

Other configurations of the second embodiment are the same as the configurations of the first embodiment.

[Production Method for Semiconductor Device]Next, a production method for the semiconductor device 2 according to the second embodiment will be described. FIG. 12 to FIG. 21 are cross-sectional diagrams illustrating the production method for the semiconductor device 2 according to the second embodiment.

First, as illustrated in FIG. 12, the semiconductor layer 20 is formed on the substrate 10, similar to the first embodiment. Next, the source electrode 230S and the drain electrode 230D are formed on the semiconductor layer 20. For the formation of the source electrode 230S and the drain electrode 230D, for example, a Ta layer, an Al layer, a Ta layer, and a Ti layer are grown through vapor deposition using a growth mask, followed by removal of the growth mask. That is, the source electrode 230S and the drain electrode 230D can be formed, for example, through vapor deposition and lift-off.

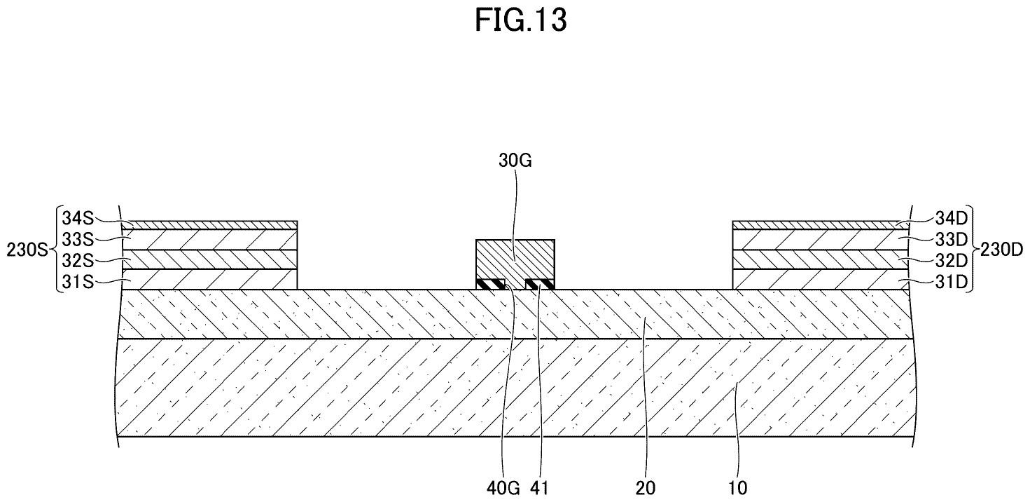

Next, as illustrated in FIG. 13, the insulating layer 41 having the opening 40G, and the gate electrode 30G are formed, similar to the first embodiment.

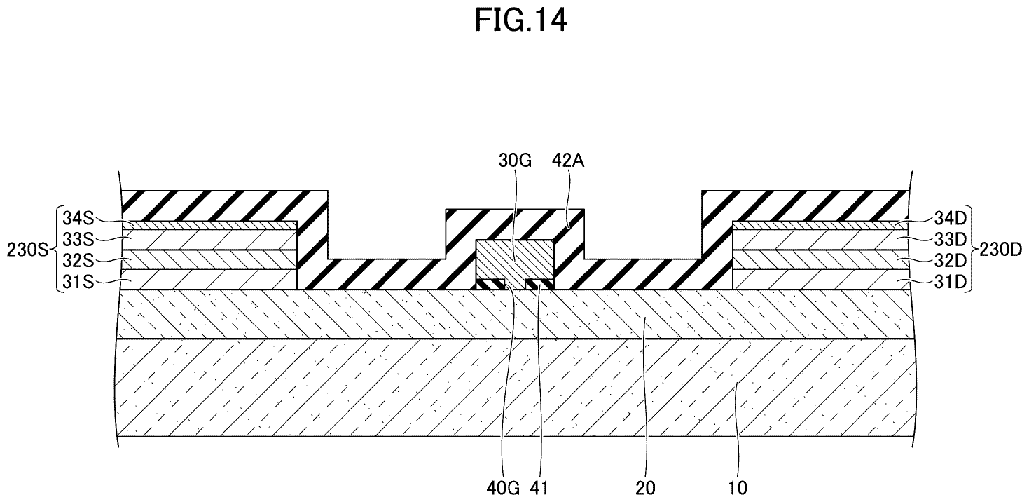

Next, as illustrated in FIG. 14, the insulating layer 42A covering the gate electrode 30G, the insulating layer 41, the semiconductor layer 20, the source electrode 230S, and the drain electrode 230D is formed. The insulating layer 42A can be formed, for example, through plasma CVD. The resistance of the Ti layers 34S and 34D to etching using the fluorine-containing reactive gas is higher than the resistance of the insulating layer 42A to etching using the fluorine-containing reactive gas. The resistance of the insulating layer 42A to etching using the chlorine-containing reactive gas is higher than the resistance of the insulating layer 43 to etching using the chlorine-containing reactive gas. The insulating layer 42A is, for example, an SiO₂ layer.

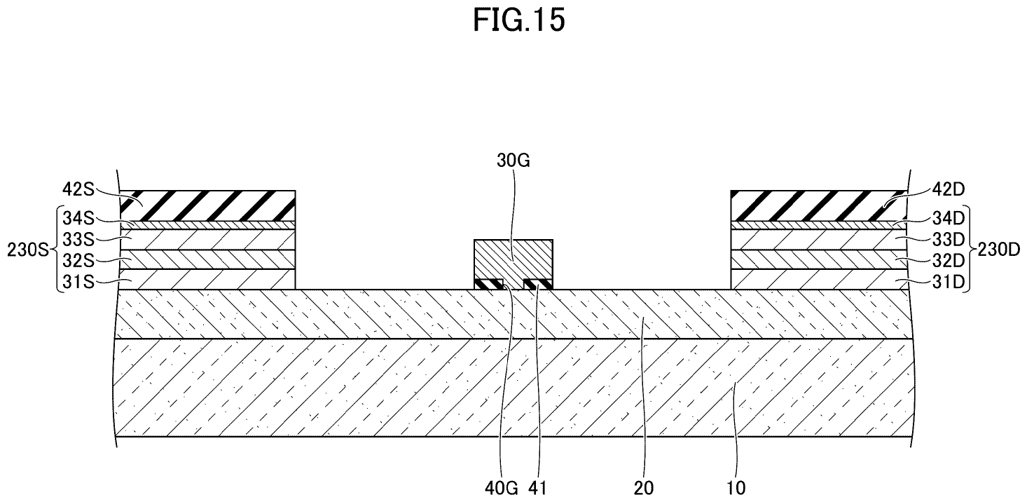

Next, by etching the insulating layer 42A, the insulating layer 42S on the Ti layer 34S and the insulating layer 42D on the Ti layer 34D are formed from the insulating layer 42A, as illustrated in FIG. 15. For the formation of the insulating layers 42S and 42D, for example, wet etching of the insulating layer 42A using a resist pattern as a mask is performed. In the formation of the insulating layers 42S and 42D, RIE of the insulating layer 42A using a resist pattern as a mask may be performed.

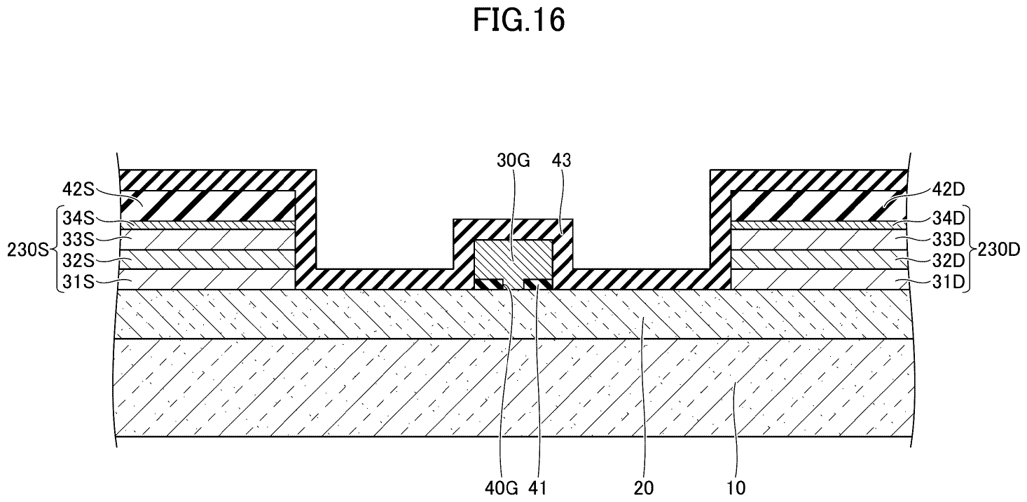

Next, as illustrated in FIG. 16, the insulating layer 43 is formed to cover the gate electrode 30G, the insulating layer 41, the semiconductor layer 20, the insulating layer 42S, the source electrode 230S, the insulating layer 42D, and the drain electrode 230D.

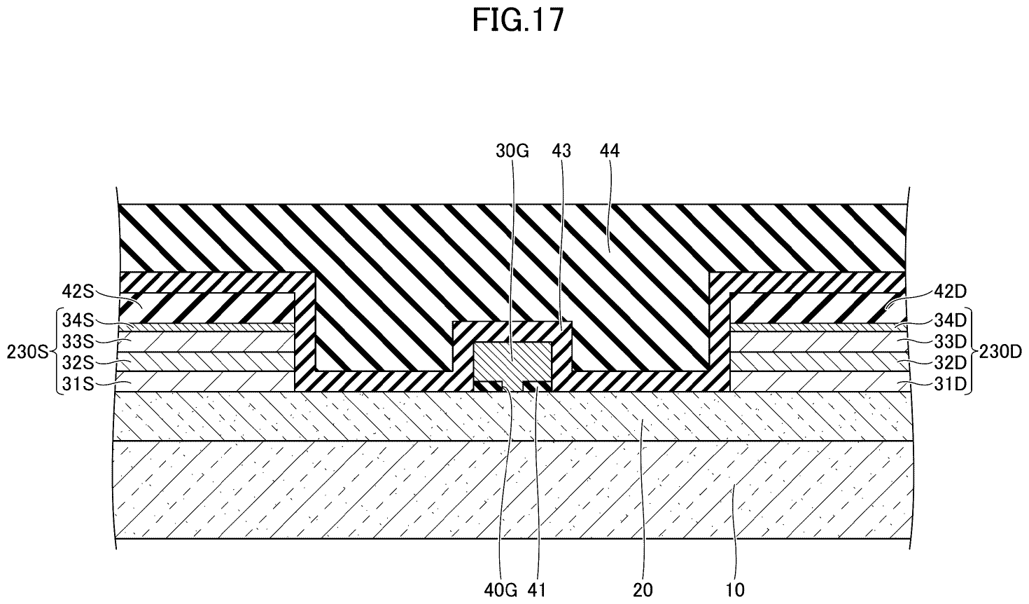

Next, as illustrated in FIG. 17, the insulating layer 44 is formed on the insulating layer 43, similar to the first embodiment.

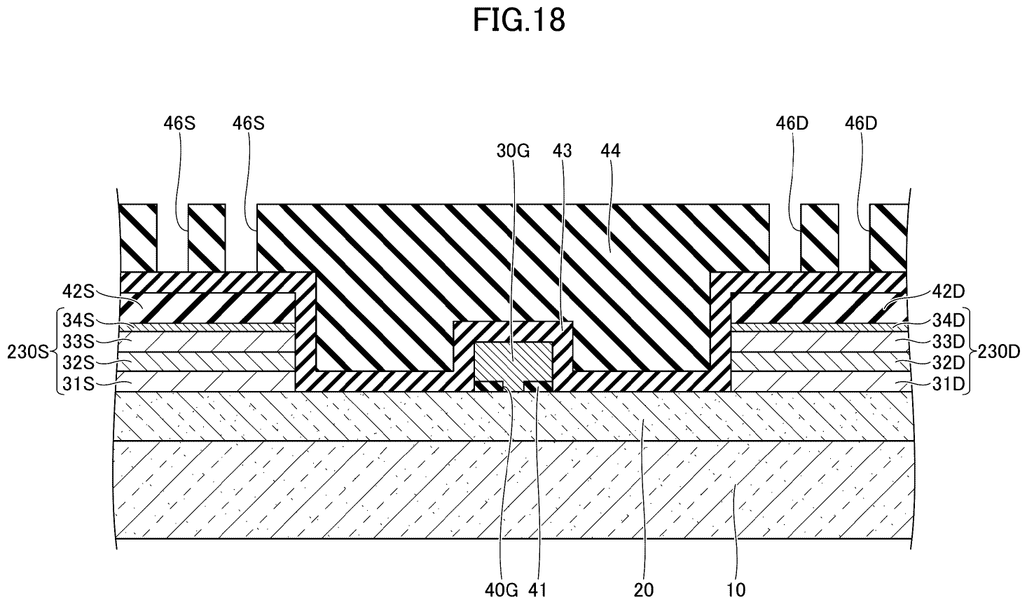

Next, as illustrated in FIG. 18, the openings 46S and the openings 46D are formed in the insulating layer 44, similar to the first embodiment. The openings 46S are formed in portions of the insulating layer 44 where the contact holes 40S are to be formed, and the openings 46D are formed in portions of the insulating layer 44 where the contact holes 40D are to be formed.

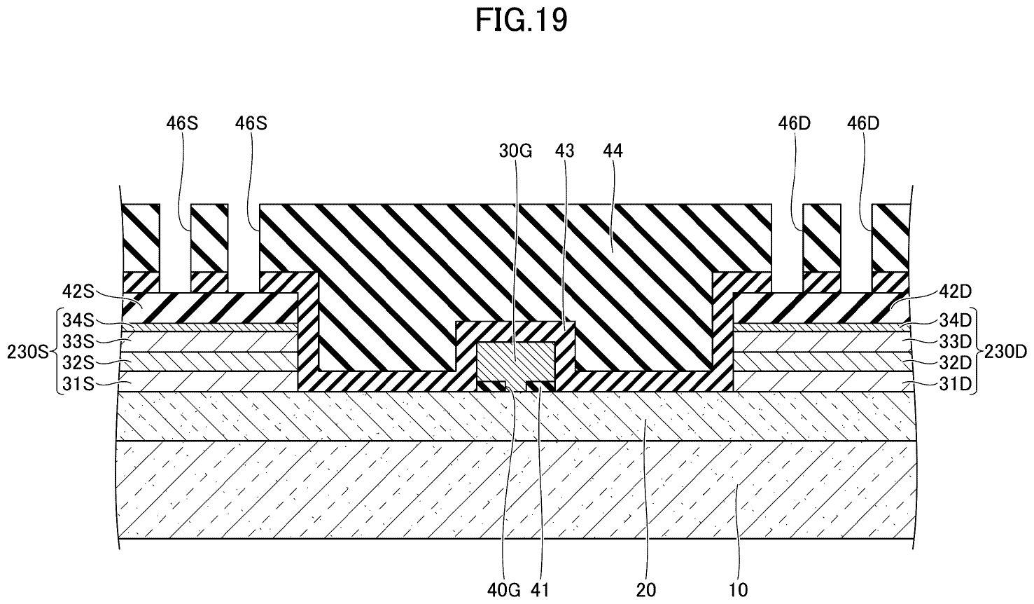

Next, as illustrated in FIG. 19, by etching portions of the insulating layer 43 that are exposed from the openings 46S and portions of the insulating layer 43 that are exposed from the openings 46D, the openings 46S and the openings 46D are extended. For the etching of the insulating layer 43, for example, RIE of the insulating layer 43 using a resist pattern as a mask is performed. In the RIE of the insulating layer 43, for example, a chlorine-containing reactive gas and an Ar plasma are used. Here, the resistance of the insulating layers 42S and 42D to etching using the chlorine-containing reactive gas is higher than the resistance of the insulating layer 43 to etching using the chlorine-containing reactive gas. Thus, the insulating layers 42S and 42D are not appreciably etched, and the insulating layers 42S and 42D function as an etching stopper.

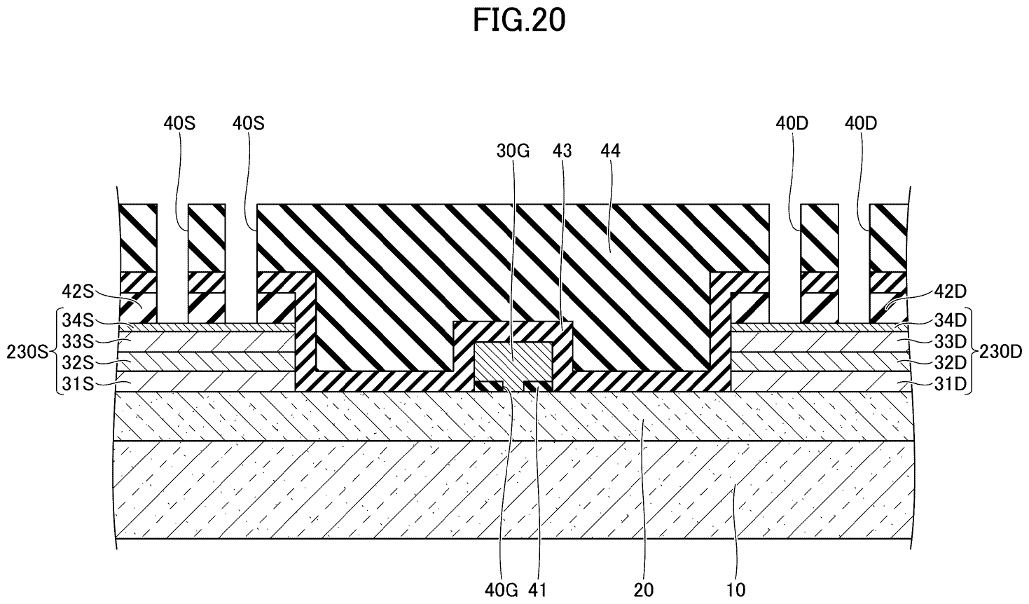

Next, as illustrated in FIG. 20, by etching portions of the insulating layer 42S that are exposed from the openings 46S, thereby extending the openings 46S, the contact holes 40S are formed in the insulating layers 42S, 43, and 44. Also, by etching portions of the insulating layer 42D that are exposed from the openings 46D, thereby extending the openings 46D, the contact holes 40D are formed in the insulating layers 42D, 43, and 44. The contact holes 40S penetrate the insulating layers 42S, 43, and 44, and the contact holes 40D penetrate the insulating layers 42D, 43, and 44. For the etching of the insulating layers 42S and 42D, for example, RIE of the insulating layers 42S and 42D using a resist pattern as a mask is performed. In the RIE of the insulating layers 42S and 42D, for example, a fluorine-containing reactive gas, such as CHF₃ or the like, is used. Here, the resistance of the Ti layer 34S to etching using the fluorine-containing reactive gas is higher than the resistance of the insulating layer 42S to etching using the fluorine-containing reactive gas. Thus, the Ti layer 34S is not appreciably etched, and the Ti layer 34S functions as an etching stopper. Also, the resistance of the Ti layer 34D to etching using the fluorine-containing reactive gas is higher than the resistance of the insulating layer 42D to etching using the fluorine-containing reactive gas. Thus, the Ti layer 34D is not appreciably etched, and the Ti layer 34D functions as an etching stopper. In the contact holes 40S and the contact holes 40D, the portions formed in the insulating layer 44 are an example of the first opening, the portions formed in the insulating layer 43 are an example of the second opening, and the portions formed in the insulating layer 42S or 42D are an example of the third opening.

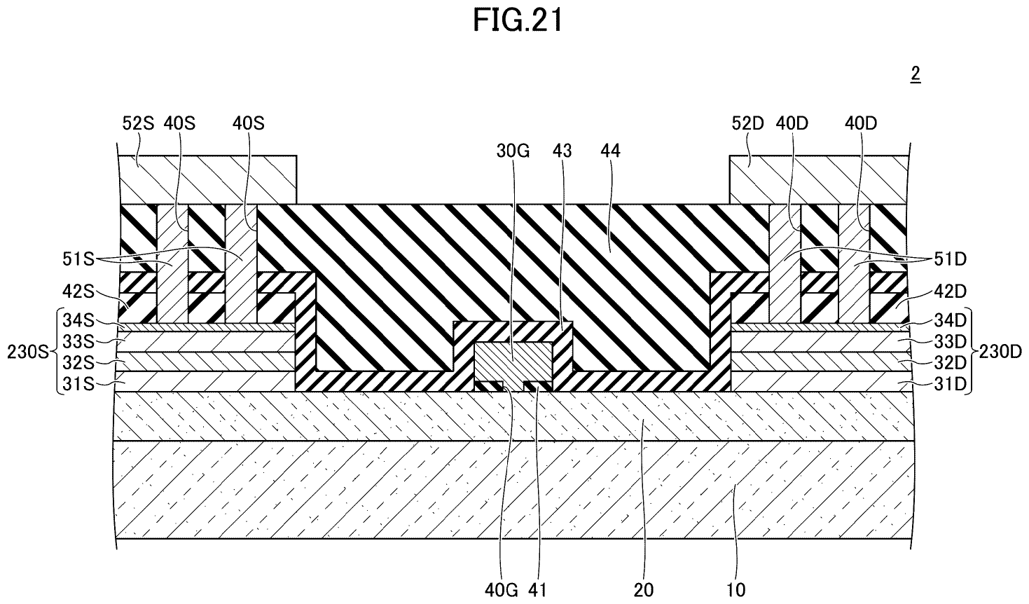

Next, as illustrated in FIG. 21, the conductive plugs 51S are formed in the contact holes 40S, and the conductive plugs 51D are formed in the contact holes 40D, similar to the first embodiment. Next, the source interconnect 52S and the drain interconnect 52D are formed on the insulating layer 44, similar to the first embodiment.

In this manner, the semiconductor device 2 according to the second embodiment can be produced.

The second embodiment also provides the same effects as the effects of the first embodiment. In the second embodiment, the insulating layer 43 functions as an etching stopper upon etching of the insulating layer 44, and the insulating layers 42S and 42D function as an etching stopper upon etching of the insulating layer 43. Also, the Ti layer 34S functions as an etching stopper upon etching of the insulating layer 42S, and the Ti layer 34D functions as an etching stopper upon etching of the insulating layer 42D. Therefore, the contact holes 40S and the contact holes 40D are readily formed. For example, even if etching of the insulating layer 43 is performed at a high power, damage to the source electrode 230S and the drain electrode 230D can be prevented.

### Third Embodiment

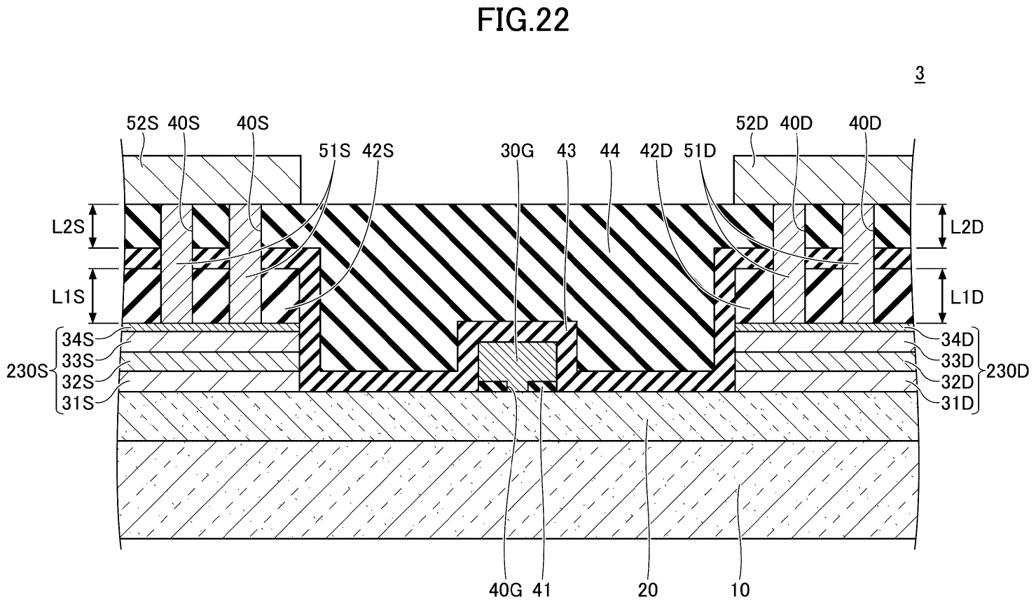

The third embodiment will be described below. The third embodiment differs from the second embodiment mainly in terms of the relation between the thicknesses of the insulating layers 42S, 42D, and 44. FIG. 22 is a cross-sectional diagram illustrating a semiconductor device according to the third embodiment.

As illustrated in FIG. 22, in a semiconductor device 3 according to the third embodiment, the insulating layer 42S is thicker than the insulating layer 44 between the source electrode 230S and the source interconnect 52S. From another viewpoint, between the source electrode 230S and the source interconnect 52S, a distance LIS between the source electrode 230S and the insulating layer 43 is larger than a distance L2S between the source interconnect 52S and the insulating layer 43. Also, between the drain electrode 230D and the drain interconnect 52D, the insulating layer 42D is thicker than the insulating layer 44. From another viewpoint, between the drain electrode 230D and the drain interconnect 52D, a distance LID between the drain electrode 230D and the insulating layer 43 is larger than a distance L2D between the drain interconnect 52D and the insulating layer 43.

Other configurations of the third embodiment are the same as the configurations of the second embodiment.

The third embodiment also provides the same effects as the effects of the second embodiment. Also, in the third embodiment, the distance LIS is larger than the distance L2S, and thus, compared to when the distance LIS is smaller than the distance L2S, the transfer path of heat in the conductive plug 51S can be shortened. Similarly, the distance LID is larger than the distance L2D, and thus, compared to when the distance LID is smaller than the distance L2D, the transfer path of heat in the conductive plug 51D can be shortened. Therefore, heat can be transferred to the source interconnect 52S and the drain interconnect 52D with higher efficiency. The thermal conductivity of tungsten, an example of a material used for the conductive plugs 51S and 51D, is approximately 150 W/(m·K).

### Fourth Embodiment

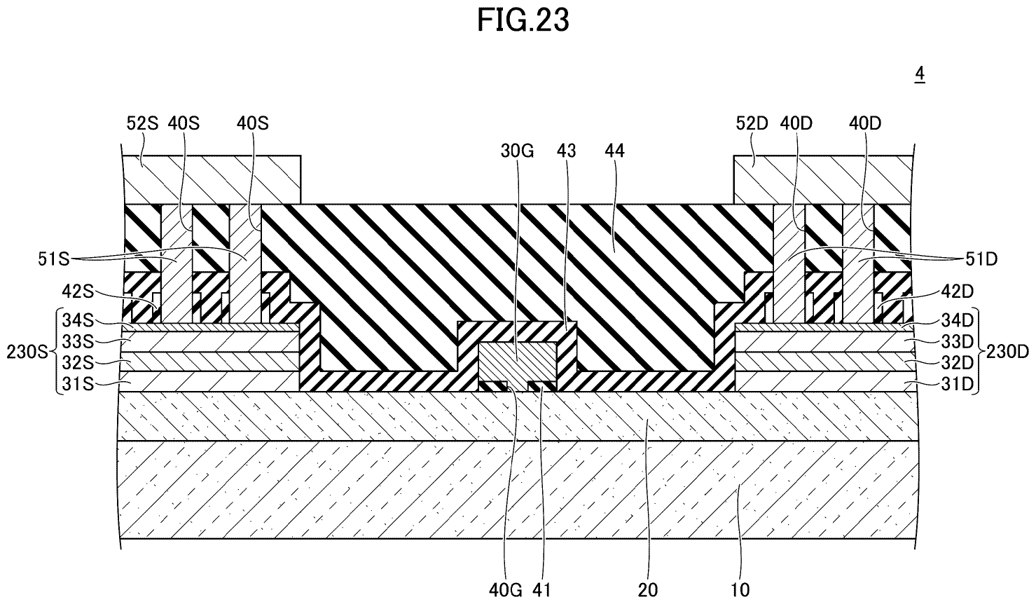

The fourth embodiment will be described below. The fourth embodiment differs from the second embodiment mainly in terms of the configuration of the insulating layers 42S, 42D, and 43. FIG. 23 is a cross-sectional diagram illustrating a semiconductor device according to the fourth embodiment.

As illustrated in FIG. 23, in a semiconductor device 4 according to the fourth embodiment, the insulating layer 42S is locally formed on the Ti layer 34S, and the insulating layer 42D is locally formed on the Ti layer 34D. Similar to the second embodiment, the contact holes 40S are formed in the insulating layers 42S, 43, and 44, and penetrate the insulating layers 42S, 43, and 44. Also, similar to the second embodiment, the contact holes 40D are formed in the insulating layers 42D, 43, and 44, and penetrate the insulating layers 42D, 43, and 44. The insulating layer 43 is inserted between the insulating layers 42S next to each other and between the insulating layers 42D next to each other.

Other configurations of the fourth embodiment are the same as the configurations of the second embodiment.

The fourth embodiment also provides the same effects as the effects of the second embodiment. The Ti layer 34S may be locally formed in the same manner as in the insulating layer 42S as long as the Ti layer 34S is formed in portions where the contact holes 40S are to be formed. Similarly, the Ti layer 34D may be locally formed in the same manner as in the insulating layer 42D as long as the Ti layer 34D is formed in portions where the contact holes 40D are to be formed.

### Fifth Embodiment

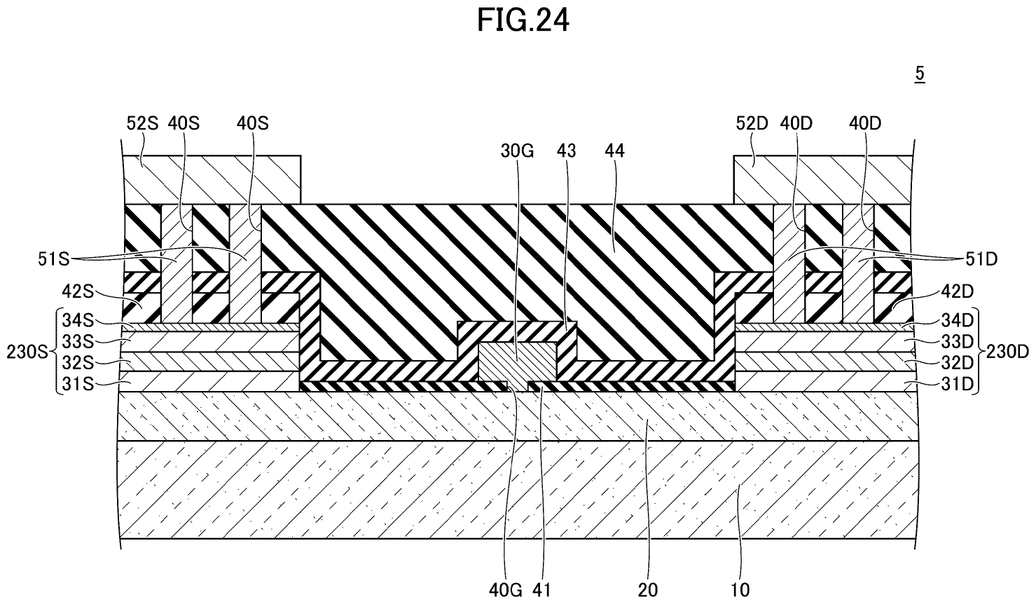

The fifth embodiment will be described below. The fifth embodiment differs from the second embodiment mainly in terms of the configuration of the insulating layer 41. FIG. 24 is a cross-sectional diagram illustrating a semiconductor device according to the fifth embodiment.

As illustrated in FIG. 24, in a semiconductor device 5 according to the fifth embodiment, the entire surface of the semiconductor layer 20 is covered with the insulating layer 41 between the source electrode 230S and the gate electrode 30G, and the entire surface of the semiconductor layer 20 is covered with the insulating layer 41 between the drain electrode 230D and the gate electrode 30G. The insulating layer 43 is also provided on the insulating layer 41 between the source electrode 230S and the gate electrode 30G and between the drain electrode 230D and the gate electrode 30G, and is apart from the semiconductor layer 20.

Other configurations of the fifth embodiment are the same as the configurations of the second embodiment.

Similar to the second embodiment, the fifth embodiment can discharge heat through the gate electrode 30G with high efficiency. Also, in the fifth embodiment, a wide range of the surface of the semiconductor layer 20 is readily protected by the insulating layer 41. For example, dangling bonds on the surface of the semiconductor layer 20 are readily reduced.

Although embodiments have been described above in detail, the present disclosure is not limited to the specific embodiments, and various variations and modifications are possible within the scope of claims recited.

What is claimed is:

1. A semiconductor device, comprising:
a substrate;
a semiconductor layer on the substrate;
a first main electrode and a second main electrode that are on the semiconductor layer;
a control electrode that is on the semiconductor layer and is between the first main electrode and the second main electrode;
a first insulating layer that is in direct contact with the control electrode and covers the first main electrode;
a second insulating layer on the first insulating layer;
a first conductive layer that penetrates the first insulating layer and the second insulating layer, is electrically connected to the first main electrode, and is in direct contact with the first insulating layer; and
a second conductive layer that is on the second insulating layer and is in direct contact with the first conductive layer, wherein
the first insulating layer includes aluminum nitride.

2. The semiconductor device according to claim 1, wherein
the first insulating layer is in direct contact with the semiconductor layer.

3. The semiconductor device according to claim 1, wherein
resistance of the first insulating layer to etching using a fluorine-containing reactive gas is higher than resistance of the second insulating layer to etching using the fluorine-containing reactive gas.

4. The semiconductor device according to claim 1, further comprising:
a third insulating layer that is between the first main electrode and the first insulating layer and that the first conductive layer penetrates, wherein
resistance of the third insulating layer to etching using a chlorine-containing reactive gas is higher than resistance of the first insulating layer to etching using the chlorine-containing reactive gas.

5. The semiconductor device according to claim 4, wherein
between the first main electrode and the second conductive layer, a distance between the first main electrode and the first insulating layer is larger than a distance between the second conductive layer and the first insulating layer.

6. The semiconductor device according to claim 4, wherein
the first main electrode includes a third conductive layer that is in direct contact with the first conductive layer and the third insulating layer, and
resistance of the third conductive layer to etching using a fluorine-containing reactive gas is higher than resistance of the third insulating layer to etching using the fluorine-containing reactive gas.

7. The semiconductor device according to claim 6, wherein
the third conductive layer is a titanium layer.

8. The semiconductor device according to claim 1, further comprising:
a fourth conductive layer that penetrates the first insulating layer and the second insulating layer, is electrically connected to the second main electrode, and is in direct contact with the first insulating layer; and
a fifth conductive layer that is on the second insulating layer and is in direct contact with the fourth conductive layer.

9. The semiconductor device according to claim 8, further comprising:
a fourth insulating layer that is between the second main electrode and the first insulating layer and that the fourth conductive layer penetrates, wherein
resistance of the fourth insulating layer to etching using a chlorine-containing reactive gas is higher than resistance of the first insulating layer to etching using the chlorine-containing reactive gas.

10. The semiconductor device according to claim 9, wherein
between the second main electrode and the fifth conductive layer, a distance between the second main electrode and the first insulating layer is larger than a distance between the fifth conductive layer and the first insulating layer.

11. The semiconductor device according to claim 9, wherein
the second main electrode includes a sixth conductive layer that is in direct contact with the fourth conductive layer and the fourth insulating layer, and
resistance of the sixth conductive layer to etching using a fluorine-containing reactive gas is higher than resistance of the fourth insulating layer to etching using the fluorine-containing reactive gas.

12. The semiconductor device according to claim 11, wherein
the sixth conductive layer is a titanium layer.

13. A production method for a semiconductor device, the production method comprising:
forming a semiconductor layer on a substrate;
forming a first main electrode and a second main electrode on the semiconductor layer;
forming a control electrode on the semiconductor layer and between the first main electrode and the second main electrode;
forming a first insulating layer so as to be in direct contact with the control electrode and cover the first main electrode;
forming a second insulating layer on the first insulating layer;
forming a contact hole in the first insulating layer and the second insulating layer so as to penetrate the first insulating layer and the second insulating layer and reach the first main electrode;
forming a first conductive layer in the contact hole so as to be electrically connected to the first main electrode and be in direct contact with the first insulating layer; and
forming a second conductive layer on the second insulating layer so as to be in direct contact with the first conductive layer, wherein
the first insulating layer includes aluminum nitride.

14. The production method for the semiconductor device according to claim 13, wherein
resistance of the first insulating layer to etching using a fluorine-containing reactive gas is higher than resistance of the second insulating layer to etching using the fluorine-containing reactive gas, and
the formation of the contact hole includes
forming a first opening so as to penetrate the second insulating layer and reach the first insulating layer by etching using the fluorine-containing reactive gas, and
forming a second opening so as to penetrate the first insulating layer by etching of a portion of the first insulating layer exposed from the first opening.

15. The production method for the semiconductor device according to claim 14, further comprising:
forming a third insulating layer on the first main electrode between the formation of the first main electrode and the second main electrode and the formation of the first insulating layer, wherein
resistance of the third insulating layer to etching using a chlorine-containing reactive gas is higher than resistance of the first insulating layer to etching using the chlorine-containing reactive gas,
the first insulating layer covers the third insulating layer, and
the formation of the second opening includes
etching the portion of the first insulating layer exposed from the first opening using the chlorine-containing reactive gas.

16. The production method for the semiconductor device according to claim 15, wherein
the formation of the first main electrode includes
forming a third conductive layer so as to be in direct contact with the third insulating layer,
resistance of the third conductive layer to etching using the fluorine-containing reactive gas is higher than resistance of the third insulating layer to etching using the fluorine-containing reactive gas, and
the formation of the contact hole includes
forming a third opening so as to penetrate the third insulating layer by etching of a portion of the third insulating layer exposed from the second opening using the fluorine-containing reactive gas.
